(19) United States
(12) Patent Application Publication
(10) Pub. No.: US 2012/0304762 A1
(43) Pub. Date: Dec. 6, 2012

(54) METHOD FOR MAKING A PYROLYTIC BORON NITRIDE ARTICLE

(76) Inventors: Caixuan XU, Urayasu-shi (JP); Subbanna MANJUNATH, Bangalore (IN); Takayuki TOGAWA, Himeji-shi (JP)

(21) Appl. No.: 13/152,581

(22) Filed: Jun. 3, 2011

(51) Int. Cl. G01N 9/00; C01B 21/064; B32B 9/04; C23C 16/01; C23C 16/34

(52) U.S. Cl. 73/32 A; 264/81; 427/255.38; 428/688; 423/290

(57) ABSTRACT

A method for producing a pyrolytic boron nitride (PBN) article comprises introducing a nitrogen containing gas and a boron containing gas into a heated reactor furnace under temperature and pressure conditions sufficient to form a PBN deposit and pulsing the flow of the reactant gases between an on and an off state. The method provides a multi-layered PBN article that exhibits a relatively weak bonding interface between adjacent PBN layers to allow for the layers to be peeled away from one another in a controlled manner.

### BACKGROUND

Pyrolytic boron nitride is formed by chemical vapor deposition using a process described in U.S. Pat. No. 3,182,006, the disclosure of which is herein incorporated by reference. The process involves introducing vapors of ammonia and a gaseous boron halide such as boron trichloride (BCl₃) in a suitable ratio into a heated furnace reactor causing boron nitride to be deposited on the surface of an appropriate substrate such as graphite. The boron nitride is deposited in layers and may be separated from the substrate to form a free standing structure of pyrolytic boron nitride. Pyrolytic boron nitride is an anisotropic material having an hexagonal crystal lattice with properties perpendicular to the basal plane, known as the “c-plane,” which are significantly different from its properties parallel to the plane, known as the “a-plane.” Because of the high degree of anisotropy the mechanical strength of the free standing pyrolytic boron nitride (hereafter “PBN”) structure is weak in the perpendicular direction, which is the direction of PBN layer growth.

Crucibles of PBN are used commercially to melt compounds at elevated temperatures. For example, in the production of semiconductors, crucibles of PBN are used to grow GaAs crystals. A PBN crucible is, however, subject to fracture from a build up of stress. For example when using the Liquid Encapsulated Czochralski method to produce single crystals of GaAs, fracture of the PBN crucible can occur after the crystal is grown and a boric oxide glass B₂O₃, which is used to cover part of the molten mass, freezes in the crucible. On freezing, the boric oxide (B₂O₃) glass shrinks more than the crucible. The resultant shrinkage mismatch generates stresses within the PBN crucible that can cause it to fracture. Similarly boric oxide is often used as an encapsulant for GaAs in the vertical gradient freeze (VGF) method. The bond between the boric oxide and the PBN surface and the shrinkage mismatch of the boric oxide and PBN on cooling causes a radial tensile stress (perpendicular to the layers) and a compressive stress (parallel to the layers) in the PBN. This causes large stresses to develop in the PBN which, in turn, can cause delamination, i.e., peeling to occur or fracture. Ideally, the PBN should peel away in thin layers of controlled thickness, providing an improved and predictable service life which would also reduce the risk of catastrophic failure. In conventional PBN crucibles, there is generally no way to predict the number of layers that will peel off. For a crucible to have a long service life, it is necessary to control peeling and to preferably limit peeling to a single selected PBN layer of controlled thickness for each crystal growth run. Moreover, the single selected layer should peel uniformly from the body of the crucible when the boric oxide glass is withdrawn.

### SUMMARY

The present invention provides a method for a making a pyrolytic boron nitride article having a plurality of PBN layers. The method provides a PBN article with layers of controlled thicknesses and which article exhibits controlled peeling of the layers, which may provide an article with a long service life. In embodiments, the method provides a PBN article comprising a plurality of PBN layers bonded by a weak bonding interface between the PBN layers. Additionally, the method allows for the production of a multi-walled PBN article that exhibits controlled peeling of the layers without the need for introducing a dopant into the system or the resulting PBN article.

In one aspect, the present invention provides a method for forming pyrolytic boron nitride comprising introducing ammonia gas and a boron halide gas into a heated furnace reactor for a first period of time, reacting the ammonia and the boron halide and causing boron nitride to be deposited on a substrate; after the first period of time, pulsing the flow of the ammonia gas and the boron halide gas into the reactor between a first pulsed state and a second pulsed state, the first pulsed state comprising discontinuing the flow of at least one of the ammonia gas and the boron halide gas, and the second pulsed state comprising flowing both the ammonia gas and the boron halide gas into the reactor and causing boron nitride to be deposited; wherein the pulsing step comprises cycling between the first pulsed state and the second pulsed state until a PBN article of a desired thickness has been achieved.

In one embodiment, the first pulsed state comprises discontinuing the flow of both the ammonia gas and the boron halide gas.

In one embodiment, the first pulsed state comprises discontinuing the flow of the ammonia gas.

In one embodiment, the first pulsed state comprises discontinuing the flow of the boron halide gas.

In one embodiment, the first pulsed state has a time interval of from about 0.5 to about 30 minutes.

In one embodiment, the first pulsed state has a time interval of from about 1 to about 15 minutes.

In one embodiment, the first pulsed state has a time interval of from about 5 to about 10 minutes.

In one embodiment, the second pulsed state has a time interval of from about 10 to about 150 minutes.

In one embodiment, the second pulsed stated has a time interval of about 90 to about 120 minutes.

In another aspect, the present invention provides a method for forming a PBN article comprising (a) introducing ammonia gas and boron halide gas into a heated reactor furnace and reacting the gases to form a PBN deposit on a substrate; (b) discontinuing a flow of the boron halide gas into the reactor for a selected period of time; and (c) repeating steps (a) and (b) until a PBN article of a desired thickness has been achieved.

In one embodiment, the first time interval is from about 10 to about 150 minutes.

In one embodiment, the first time interval is from about 90 to about 120 minutes.

In one embodiment, the second time interval is from about 0.5 to about 30 minutes.

In one embodiment, the second time interval is from about 1 to about 15 minutes.

In one embodiment, the first time interval is from about 90 to about 120 minutes, and the second time interval is from about 1 to about 5 minutes.

In one embodiment, step (b) further comprises discontinuing the flow of the ammonia gas during the second time interval.

In another aspect, the present invention provides a pyrolytic boron nitride article comprising a plurality of PBN layers having an interface layer disposed between the PBN layers, where the interface layer is substantially free of a dopant.

In still another aspect, the present invention provides a method for testing the peel strength of irregularly shaped PBN articles.

### BRIEF DESCRIPTION OF THE DRAWINGS

FIG. 1 is a schematic illustration of a system suitable for forming a PBN article in accordance with an embodiment of the present invention;

FIG. 2 is a flow chart illustrating processing steps for forming a PBN article in accordance with an embodiment of the present invention;

FIG. 3 is a graph showing the processing steps over time for forming a PBN article in accordance with aspects of the present invention;

FIG. 4 is a schematic illustration of a PBN article formed in accordance with an embodiment of the present invention;

FIG. 5 is a photomicrogaph of a PBN article formed by a method in accordance with an embodiment the present invention; and

FIG. 6 is a photomicrograph of PBN article formed by conventional processing methods.

### DETAILED DESCRIPTION

The present invention provides a method for forming a PBN article having multiple layers. The method provides for the formation of a multi-walled PBN article having layers of controlled thickness with an interface layer disposed between the layers. The interface layer provides a bonding interface between adjacent PBN layers having a relatively low bond strength to allow for adjacent layers to be peeled away from one another in a controlled manner.

The present method comprises forming a multi-layered PBN article by providing a pulsed flow chemical vapor deposition of PBN. PBN may be produced by the vapor phase reaction of ammonia and a boron halide. The gaseous reactants are fed into a heated reactor furnace and reacted with each other at an elevated temperature and under pressure to form boron nitride, which is deposited on a substrate. In accordance with the present method, forming the PBN article comprises pulsing the flow of the reactants into the reactor by providing intervals where both reactants are flowed into the reactor to form a PBN and intervals where the flow of one or more of the reactants is discontinued or shut off.

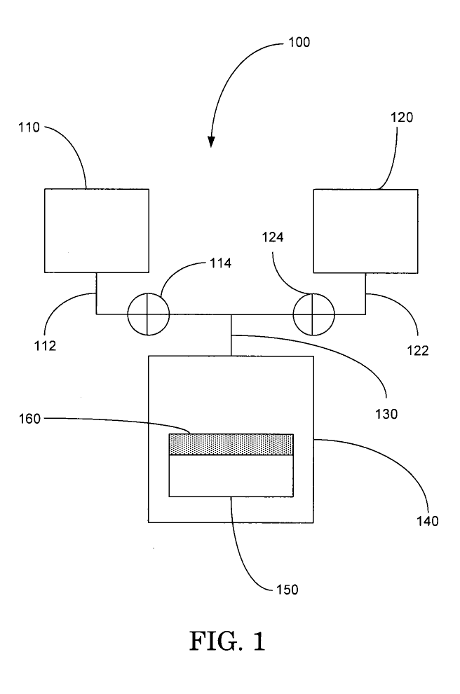

The method may employ a system 100 as shown in FIG. 1. As shown in FIG. 1, the system 100 includes a source 110 of ammonia (NH₃) and a source 120 of a boron-containing gas (e.g., a boron halide). The gaseous reactants are fed from the reactant sources 110 and 120 through feed lines 112 and 122, respectively, to feed line 130 where the reactant gases are initially mixed and then fed into the reactor 140. It will be appreciated that the method and system could be configured without feed line 130, and the reactants could be separately introduced into the reactor. The mixture of the reactant gases is reacted in the reactor 140 at a suitable temperature and pressure to cause PBN to be deposited onto a substrate. In one embodiment, the temperature may be about 1,450° C. to about 2,300° C., and the pressure may be below about 50 mm of mercury. The reactant gases react with each other under the selected temperature and pressure conditions to cause a PBN deposit 160 to form on a substrate 150.

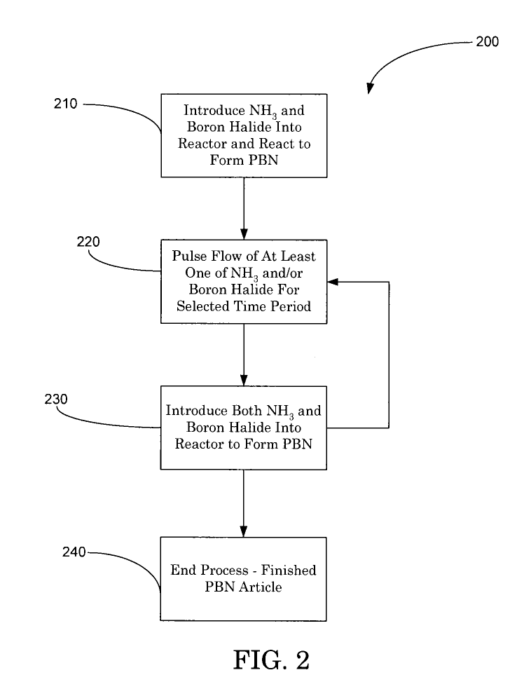

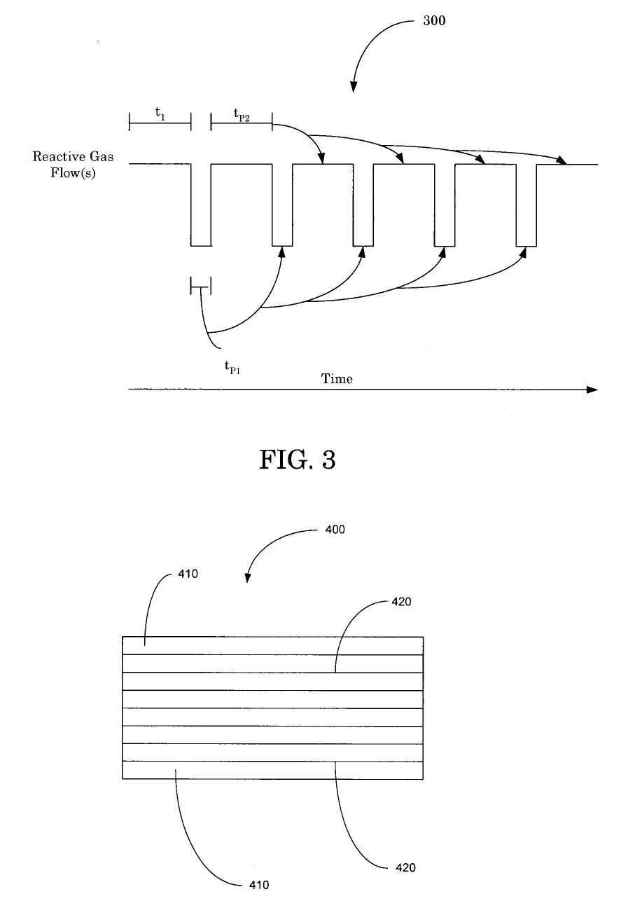

In accordance with the present invention, a method for forming a PBN article comprises pulsing the flow of one or more of the reactant gases for selected time intervals. FIG. 2 illustrates a flow diagram for a process 200 of forming PBN in accordance with an embodiment of the present invention. At step 210, the gaseous reactants are both introduced into the heated reactor and reacted under temperature and pressure conditions to cause PBN to deposit on a substrate. The reaction of the reactant gases in step 210 may be carried out, for example, for a first or initial time period t₁ (FIG. 3) to form a PBN deposit of a desired thickness.

After forming a first PBN layer or deposit of a desired thickness, the method comprises pulsing the flow of the reactant gases, which is illustrated in steps 220 and 230 in FIG. 2. In step 220, the method comprises discontinuing the flow of at least one of the reactant gases into the heated reactor for a selected time interval (e.g., t_{P1} in FIG. 3). Discontinuing the flow of at least one of the reactant gases may also be referred to herein as the “first pulsed state” or the “gas off state.” In one embodiment, the first pulsed state may comprise discontinuing the flow of both the ammonia gas and the boron halide gas into the reactor for a selected time interval. In another embodiment, the first pulsed state may comprise discontinuing the flow of the ammonia gas into the reactor for a selected time interval. In still another embodiment, the first pulsed state may comprise discontinuing the flow of the boron halide gas into the reactor for a selected time interval.

Following step 220, the method proceeds to step 230 where both reactant gases are again introduced into the heated reactor and reacted for a selected time interval (e.g., t_{P2} in FIG. 3) to form another PBN layer over the previously formed PBN layer. The step of introducing both reactants into the reactor following a step of discontinuing the flow of at least one of the reactant gases may also be referred to herein as “the second pulsed state.” As illustrated in FIG. 2, the pulsing steps 220 and 230 may be repeated (See, e.g., FIG. 3) as necessary until a PBN article of a desired thickness is achieved in step 240.

FIG. 3 is a schematic representation illustrating the gas flow 300 of the reactants over time for the pulsing steps. The pulse states illustrated by time intervals t₁ and t_{P2} relate to the flow of both reactant gases into the reactor. It will be appreciated that the time intervals t₁ and t_{P2} may be the same or different, and the time interval t_{P2} may be the same or varied over the course of the process. The pulsed state occurring during time interval t_{P1} may be a state where the flow of one or both of the reactant gases is discontinued. The time interval t_{P1} may be constant or varied over the course of the process. It will also be appreciated that the flow rates of the gases may be the same or varied during different pulsing steps.

For the deposition of PBN, the nitrogen containing gas and the boron containing gas are generally provided at a concentration and flow rate to provide a boron to nitrogen ratio of about 1:1 in the PBN deposit. In one embodiment, the reactant gases are provided in an amount of at least one mole of ammonia per mole of boron halide. It will be appreciated that excess ammonia may be used and introduced into the reactor during processing. In one embodiment, from about 1 to about 3.5 moles of ammonia are employed per mole of boron halide. In another embodiment, from about 1.3 to about 3 moles of ammonia are employed per mole of boron halide during the deposition of PBN (e.g., during the initial deposition and during the second pulsed state).

In one embodiment, during introduction of both reactant gases into the reactor for deposition of PBN (e.g., during the deposition of the initial PBN layer or during the second pulsed state), the ammonia may be introduced at a rate of from about 1.5 standard liters per minute (slpm) to about 6.5 slpm. In another embodiment, the ammonia may be introduced into the reactor at a flow rate of from about 2.5 to about 4.5 slpm. In one embodiment, the boron halide is introduced into the reactor at a flow rate of from about 0.8 slpm to about 2.0 slpm. In another embodiment, the boron halide is introduced into the reactor at a flow rate of from about 1.2 slpm to about 1.8 slpm.

The reactants are both introduced into and flowed through the reactor for a selected period of time to provide a PBN deposit of a desired thickness. In one embodiment, the nitrogen containing gas and boron containing gas are both introduced into the reactor (e.g., during time t₁ or t_{P2}) for a time interval of from about 10 to about 150 minutes to provide a PBN deposit. In another embodiment, the time interval for introducing both reactants into the reactor is from about 90 to about 120 minutes. The time interval t_{P2} (for the second pulsed state introducing both reactants into the reactor) may be the same or different than the time interval of t₁. Additionally, the time interval t_{P2} may be the same throughout the process or it may be varied as desired to provide layers of different thickness. The deposition rate may be controlled to provide a PBN layer of a desired thickness. In one embodiment, the PBN layer(s) may independently have a thickness of from about 1 μm to about 2 mm. In another embodiment, the layers independently have a thickness of from about 5 μm to about 500 μm. In another embodiment, the layers independently have a thickness of from about 10 μm to about 200 μm.

The pulsing step of discontinuing the flow of at least one of the reactant gases into the reactor (e.g., step 220 in FIG. 2) may include discontinuing the flow of one or both reactant gases into the reactor. In one embodiment, the first pulsed state comprises discontinuing the flow of ammonia into the reactor for a selected time interval. In another embodiment, the first pulsed state comprises discontinuing the flow of boron halide into the reactor for a selected time interval. In still another embodiment the first pulsed state comprises discontinuing the flow of both the ammonia and the boron halide for a selected time interval. The time interval (e.g., tₚ₁) of the first pulsed state/gas off intervals may be selected as desired. In one embodiment the time interval of the first pulsed state is from about 0.5 to about 30 minutes. In another embodiment, the time interval of the first pulsed state is from about 1 to about 15 minutes. In still another embodiment, the time interval of the first pulsed state is from about 5 to about 10 minutes. In yet another embodiment, the time interval of the first pulsed state is about 1 minute. The time intervals tₒ may be constant or varied as desired over the course of the process to control the bonding between adjacent PBN layers (e.g., to provide weaker and stronger bonding interfaces throughout the article). Additionally, which gases are pulsed off may also be selected as desired and can be changed throughout the process.

It will be appreciated that the reactor and system may be configured with the appropriate valves and control systems to allow for the pulsing of the reactant gases between a “gas on” state in which the gases are permitted to flow into the reactor and a “gas off” state in which the flow of one or both reactants into the reactor is discontinued. Referring to FIG. 1, for example, the system 100 may include a valve 114 that may be opened or closed as desired to permit the flow of the ammonia gas into the reactor, and a valve 124 that may be opened or closed as desired to permit the flow of the boron halide gas into the reactor. The system may include the appropriate control systems and mechanisms (e.g., computer controls) (not shown)) to allow the process to be automated to control the pulsing steps and other parameters including the opening and closing of valves 114 and 124, the time intervals between the opening and closing of such valves, the flow rate of the gases, the temperature, and the like.

The flow of the reactant gases into the reactor may be assisted by a carrier gas. Suitable carrier gases include inert gases, such as nitrogen (N2), argon, and the like, that do not form part of the overall reaction. The carrier gas may still be introduced into the reactor even when the flow of one or both reactants are discontinued during the pulsing steps.

In one embodiment, the method comprises providing a PBN article by depositing a first PBN layer by reacting ammonia and a boron halide (e.g., boron trichloride) in a boron halide ammonia ratio of about 1:3 for 120 minutes (at a deposition rate of about 20 to about 80 microns per hour), and then pulsing the reactants between a first and second pulsed state, where the first pulsed state comprises discontinuing the flow of the boron halide reactant into the system for a one minute interval followed by a second pulsed state where both the boron halide and ammonia are introduced into the system for an interval of about 120 minutes. In this embodiment, the system is pulsed between the first and second pulsed states until a period of 30 hours has elapsed, at which time the reaction run is ended.

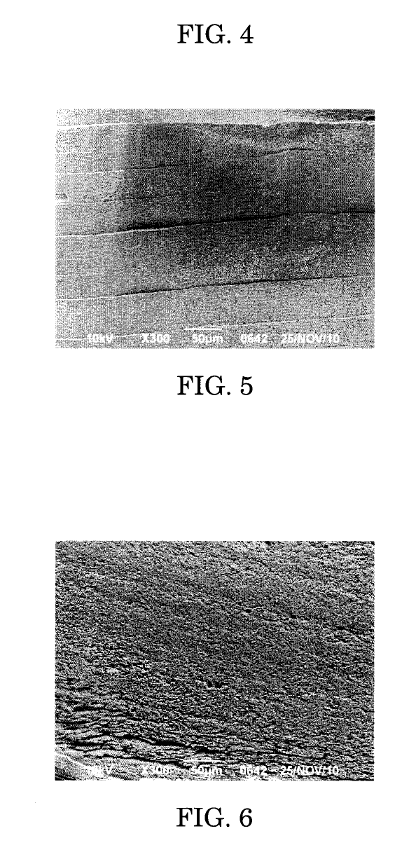

The method in accordance with the present invention provides a multi-layered PBN article. Referring to FIG. 4, the present method provides a process for producing a PBN article 400 comprising a plurality of laminated layers 410 of PBN with bonding interface 420 between adjacent layers. The interface between adjacent PBN layers is formed by the pulsed flow deposition process according to the present invention and provides a bonding interface between the PBN layers. The interfaces provide a relatively low bonding strength bond between adjacent PBN layers to allow for selected layers to be peeled away from one another along the bonding interface.

Applicants have found that the present method provides a multi-layer PBN article with a relatively weak bonding interface between adjacent PBN layers without the need for introducing a dopant into the article. As used herein, a “dopant” refers to any material other than one of the ammonia or boron halide reactant gases or a carrier gas. In particular, applicants have found that a dopant is not necessary to create a PBN article that allows for PBN layers to be peeled away from one another in a controlled manner. Thus, PBN articles formed in accordance with the present method are not susceptible to problems that may be associated with prior art articles that employ dopants, which may introduce impurities into the PBN article.

Aspects of the invention may be further understood with reference to the following examples. The examples are for the purpose of illustrating various aspects of the invention and are not intended to limit the scope of the claims in any manner.

### EXAMPLES

PBN articles are made be reacting ammonia and boron chloride at a temperature of about 1,800° C. Examples 1-5 further comprised pulsing the reactants between a first pulsed state (comprising temporarily discontinuing the flow of at least one reactant gas into the reactor) and a second pulsed state (comprising introducing both reactant gases into the system). The parameters (e.g., time period and gas flow rates) of the pulsing steps are shown in Table 1. The Comparative Example was a continuous reaction with no pulsing.

The peeling performance of the PBN articles is tested by cutting a 5 mm by 5 mm slab from the respective PBN articles and setting the articles in a 1,200 W ultrasonic bath for 10 minutes. The articles may then be examined by scanning electron microscopy. Additionally, peeling performance is tested by observing the density of delamination.

The results of the different reactions is shown in Table 1:

TABLE 1

| | | | PBN Deposition | | | | | |
|---|---|---|---|---|---|---|---|---|
| | | | Conditions (initial | | | | | |
| | First | | deposit; second | | | | | |
| | Pulsed State | | pulsed state) | | | | | |
| | Gas(es) | Interval | BC1₃ | NH₃ | Interval | Deposition | Peeling | |
| Example | pulsed off | (min) | (slpm) | (slpm) | (min) | (Microns/Hr) | performance | Yield |
| 1 | BCl3 + NH3 | 10 | 1.6 | 4.5 | 10 | 5-20 | ⊚ | 17% |
| 2 | BCl3 + NH3 | 10 | 1.6 | 4.5 | 20 | 10-30 | ⊚ | 0% |
| 3 | BCl3 + NH3 | 1 | 1.6 | 4.5 | 30 | 20-80 | ◯ | 50% |
| 4 | BCl3 | 1 | 1.6 | 4.5 | 120 | 20-80 | ◯ | 83% |
| 5 | BCl3 | 1 | 1.6 | 2.7 | 120 | 20-80 | ◯ | 67% |
| Comparative | — | — | 1.6 | 4.5 | — | 20-80 | Δ | 50% |
| Example | | | | | | | | |

To qualitatively test the peeling performance, PBN pieces with dimension as 5 mm×5 mm were cut by a diamond cutter from the crucible samples listed in table 1. Sample No. 2 had serious delamination issue and slices peeled off after cutting off from crucible. PBN pieces from samples 1-5 and the Comparative Example were set in a 1,200 W ultrasonic bath for 10 minutes. The cross sections were then observed by scanning electron microscopy. Peeling performance was qualitatively test by observing the density of delamination. Table 1 illustrates the results. Samples made from pulsing gas flow CVD process were found to have better peeling performance than reference sample. Examples 3-5 provided a PBN article with weak delamination in excellent yields. FIG. 5 and FIG. 6 are scanning electron microscopy photos from Example 4 and the Comparative Example, respectively. In FIG. 5, micro size delamination was observed with an interval as around 60 um, which coincided with the interval of pulsing gas on time deposition. The micro size delamination confirms the weak mechanical bonding interface in Example 4. No such kind of delamination was observed for continuous gas flow CVD (FIG. 6).

Embodiments of the invention have been described above and, obviously, modifications and alterations may occur to others upon the reading and understanding of this specification, including altering the identity of the metal alkoxide source to produce other metal oxide particles. The claims as follows are intended to include all modifications and alterations insofar as they come within the scope of the claims or the equivalent thereof.

Having thus described the invention, we claim:

1. A method of making a PBN article comprising:
introducing ammonia gas and a boron halide gas into a heated furnace reactor for a first period of time, reacting the ammonia and the boron halide and causing boron nitride to be deposited on a substrate;
after the first period of time, pulsing the flow of the ammonia gas and the boron halide gas into the reactor between a first pulsed state and a second pulsed state, the first pulsed state comprising discontinuing the flow of at least one of the ammonia gas and the boron halide gas, and the second pulsed state comprising flowing both the ammonia gas and the boron halide gas into the reactor and causing boron nitride to be deposited; and
pulsing between the first pulsed state and the second pulsed state until a PBN article of a desired thickness has been achieved.

2. The method of claim 1, wherein the first pulsed state comprises discontinuing the flow of both the ammonia gas and the boron halide gas.

3. The method of claim 1, wherein the first pulsed state comprises discontinuing the flow of the ammonia gas.

4. The method of claim 1, wherein the first pulsed state comprises discontinuing the flow of the boron halide gas.

5. The method of claim 1, wherein first pulsed state has a time interval of from about 0.5 to about 30 minutes.

6. The method of claim 1, wherein the first pulsed state has a time interval of from about 1 to about 15 minutes.

7. The method of claim 1, wherein the first pulsed state has a time interval of from about 5 to about 10 minutes.

8. The method of claim 1, wherein the second pulsed state has a time interval of from about 10 to about 150 minutes.

9. The method of claim 1, wherein the second pulsed stated has a time interval of about 90 to about 120 minutes.

10. A method of forming a PBN article comprising:
(a) introducing ammonia gas and boron halide gas into a heated reactor furnace and reacting the gases for a first time interval to form a PBN deposit on a substrate;
(b) discontinuing a flow of the boron halide gas into the reactor for a second time interval; and
(c) repeating steps (a) and (b) until a PBN article of a desired thickness has been achieved.

11. The method of claim 10, wherein the first time interval is from about 10 to about 150 minutes.

12. The method of claim 10, wherein the first time interval is from about 90 to about 120 minutes.

13. The method of claim 10, wherein the second time interval is from about 0.5 to about 30 minutes.

14. The method of claim 10, wherein the second time interval is from about 1 to about 15 minutes.

15. The method of claim 10, wherein the first time interval is from about 90 to about 120 minutes, and the second time interval is from about 1 to about 5 minutes.

16. The method of claim 15, wherein step (b) further comprises discontinuing the flow of the ammonia gas during the second time interval.

17. A PBN article made according to the method of claim 1.

18. A PBN article made according to the method of claim 10.

19. A PBN article comprising a plurality of PBN layers and a bonding interface layer disposed between adjacent PBN layers, wherein the bonding interface layer is substantially free of a dopant.

20. A method of testing the peeling performance of a PBN article comprising:
subjecting a slab of a PBN article to ultrasonic forces for a period of time; and
determining the density of delamination between two or more PBN layers of the PBN article.
